(19) United States
(12) Patent Application Publication
(10) Pub. No.: US 2026/0126731 A1
(43) Pub. Date: May 7, 2026

(54) METHOD FOR REDUCING ABERRATIONS OF AN OPTICAL ELEMENT, OPTICAL ELEMENT AND SEMICONDUCTOR SYSTEM

(71) Applicant: Carl Zeiss SMT GmbH, Oberkochen (DE)

(72) Inventors: Robert HARMES, Aalen (DE); Felix WAELDCHEN, Aalen (DE); Malte LANGENHORST, Aalen (DE); Werner WEISS, Ulm (DE)

(21) Appl. No.: 19/434,697

(22) Filed: Dec. 29, 2025

Related U.S. Application Data
(63) Continuation of application No. PCT/EP2024/067117, filed on Jun. 19, 2024.

(30) Foreign Application Priority Data
Jun. 27, 2023 (DE) 10 2023 206 062.0

(51) Int. Cl. G03F 7/00

(52) U.S. Cl. CPC G03F 7/706; G03F 7/70266; G03F 7/705

(57) ABSTRACT

A method for reducing aberrations of an optical element (Mi) e.g., in a lithography system includes: determining a temporal change in an optical property of the optical element (Mi), e.g., a temporal change of a surface FIGURE(P(x,y)) of a surface (24a) of a substrate (24) of the optical element (Mi), that is expected over the operational life of the optical element (Mi), with the temporal change in the optical property over the operational life (T) of the optical element (Mi) causing varying aberrations, and reducing the aberrations that vary over the operational life of the optical element (Mi) by generating an allowance, in particular a surface figure allowance (∆P_{V}), which compensates at least a portion of the total temporal change in the optical property (P(x,y)) that is expected over the operational life.

### CROSS-REFERENCE TO RELATED APPLICATION

This is a Continuation of International Application PCT/EP2024/067117, which has an international filing date of June 19, 2024, and the disclosure of which is incorporated in its entirety into the present Continuation by reference. This Continuation also claims foreign priority under 35 U.S.C. §119(a)-(d) to and also incorporates by reference, in its entirety, German Patent Application DE 102023 206 062.0 filed June 27, 2023.

### FIELD

The invention relates to a method for reducing aberrations of an optical element, in particular of an optical element in a lithography system, to an optical element, preferably a mirror, in particular an EUV mirror, and to an apparatus for semiconductor technology having at least one such optical element.

### BACKGROUND

Optical elements in the form of lens elements or mirrors represent the core elements of projection lenses, for example as used in microlithography. In such optical elements, the requirements for the imaging quality are becoming increasingly stringent and ensure that new processes and materials have to be developed for the production of these optical elements. However, depending on the material used and the process applied, the various effects may lead to a deterioration in the imaging quality over the lifetime or operational life of a respective optical element, i.e. the aberrations of the optical element typically increase irreversibly over the operational life of the optical element.

The practice of correcting surface figure errors on a surface of an optical element, i.e. deviations of a surface shape from a target surface shape of the surface, by surface processing is known.

For example, DE102018211596A1 describes a method for producing a reflective optical element for a projection exposure apparatus, with the optical element comprising a substrate. The method comprises measuring the substrate surface, irradiating the substrate with the aid of electrons or with photons and annealing the substrate. Irradiation leads to local compaction of the substrate, and this can be used for correcting surface defects. Since annealing partially reverses the compaction produced during the irradiation, the decompaction by annealing may already be kept available during the compaction in the irradiation step. Using such an allowance makes it possible to attain the target surface shape by irradiation and the subsequent annealing.

The method described in DE102018211596A1 can also be used to create protection for the substrate against progressive compaction over the service life of the substrate that is caused by irradiation with extreme ultraviolet (EUV) radiation during the operation of the reflective optical element. In order to gain this protection, irradiation is performed during the production of the optical element until compaction saturation is reached, i.e. until a state is reached in which substrate compaction no longer increases or still increases only to a negligible extent in the event of further irradiation. It is possible in the long term hereby to prevent impermissible surface deformations and associated aberrations due to the compaction of the material by EUV radiation.

In principle, time-varying aberrations or image errors that occur over long time scales can be divided into two classes: A first class of image errors that are distinguished in that their future size increases by a non-negligible amount after a constant time period, and a second class of image errors that, after reaching a threshold value, only still grow by a negligible amount after every further time period. DE102012212758A1 proposes adjusting both classes of image errors in parallel in time with the aid of manipulators of the projection lens. The first or second image error can be determined by measurement or by prediction from a prediction model.

However, it is typically not possible to use manipulators to correct all aberrations of a projection lens or a lithography system that arise over the operational life of the optical elements.

### SUMMARY

One object addressed by the invention is that of providing a method for reducing aberrations that vary over the operational life of the optical element, an optical element and an apparatus of semiconductor technology having at least one such optical element.

According to a first aspect and in one formulation, this object is addressed by a method for reducing aberrations of an optical element, comprising: determining a temporal change in an optical property of the optical element – in particular a temporal change in a surface figure of a surface of a substrate of the optical element – that is expected over the operational life of the optical element, with the temporal change in the optical property over the operational life of the optical element causing varying aberrations, and reducing the aberrations that vary over the operational life of the optical element by generating an allowance, in particular a surface figure allowance, which compensates at least a proportion of the total temporal change in the optical property that is expected over the operational life.

In the method described herein, the temporal change in an optical property of the optical element that is expected over the operational life of the optical element is initially determined. For example, the optical property may be the surface figure or the surface shape of the optical element described above, but – especially in the case of optical elements in the form of lens elements – the temporal change may also be a temporal change in the refractive index or a temporal change in the stress birefringence.

Should the expected temporal change in the optical property over the operational life be known, the aberrations that vary over the operational life of the optical element can be reduced. Here, use is made of the fact that the temporal change in the optical property over the operational life of the optical element typically either increases or decreases,

with the temporal change not necessarily being irreversible. It is possible to at least partially compensate for the temporal change in the optical property over the operational life of the optical element by generating an allowance that counteracts the temporal change. For example, given a temporal change in the surface figure which is attributable to a local increase in the thickness of the substrate of the optical element, the allowance may consist in a local reduction in the thickness of the substrate, which at least partially compensates for the local increase in the thickness of the substrate.

Depending on the manner in which the allowance is generated and depending on the effect by which the temporal change in the optical property is caused, complete compensation of the temporal change in the optical property over the operational life of the optical element might be possible. In this case, the allowance might possibly completely compensate for the aberrations over the operational life of the optical element because temporal changes in the optical property no longer occur over the operational life. However, complete compensation of the temporal change in the optical property over the operational life of the optical element is not possible in every case.

In a variant of the method, the allowance compensates a predetermined proportion, in particular a proportion of 50%, of the total temporal change in the optical property that is expected over the operational life of the optical element. In this variant, a state of the optical element is generated, as a rule by a surface figure allowance, during the production of the optical element or optionally at a later time (see below), this state of the optical element being chosen such that the surface of the substrate just has the target surface shape at a time at which 50% of the total temporal change in the optical property that is expected over the operational life of the optical element has occurred. Accordingly, the aberrations of the optical element are minimal at this time. The aberrations reduce before this time and increase again after this time; however, the surface figure allowance leads to the absolute value of the aberrations being halved over the operational life of the optical element, i.e. the maximum negative effect of the aberrations is reduced by half in comparison with the case that a target surface shape of the optical element without the surface figure allowance is generated during the production.

It is understood that the time at which 50% of the temporal change in the optical property is reached generally does not correspond to half the operational life of the optical element since the temporal change in the optical property is generally not proportional to the operational life and in particular does not increase or decrease linearly with the operational life.

It is understood that it is not mandatory for a proportion of 50% of the total temporal change in the optical property to be compensated but that also a different proportion of the temporal change can be compensated by the allowance. For example, lower aberrations or better imaging quality may be achieved at the start of the operational life by virtue of an earlier time being selected for the allowance, at which time for example only 20% or 30% of the total temporal change over the operational life is compensated. In order to keep the adaptation of the surface figure by the surface figure allowance as small as possible, the components of the aberrations that by other correction mechanisms of the optical system in which the optical element is integrated in operation, e.g. a projection lens of a lithography system, should be omitted, i.e. not taken into consideration in the surface figure allowance.

In a variant, the surface figure allowance is generated by processing the surface of the substrate, the processing comprising material-removing processing of the surface of the substrate and/or irradiating the substrate, in particular with subsequent annealing of the substrate. The surface figure allowance or surface figure correction may be generated by e.g. direct material removal. In an alternative to that or in addition, the surface figure allowance may be generated by compacting the material of the substrate in volume, optionally with subsequent annealing, for example as described in DE102018211596A1 cited at the outset, the entirety of which is incorporated into the content of this application by reference. Other measures for surface figure correction known from the literature are also possible, for example (layer) stresses introduced in a targeted manner, ion beam processing, compensation at other optical elements that are suitably arranged in the optical system in which the optical element is arranged (see

below) or optionally – at least in part – the use of actuators or manipulators present for this purpose, for example c.f. DE102012212758A1 cited at the outset, the entirety of which is incorporated into the content of this application by reference.

In a further variant, the surface figure allowance is generated by surface-processing of a surface of a substrate of another optical element of the lithography system. As described further above, the surface figure allowance can also be provided on one or more other optical elements in an optical system, a lithography system in the present case. By preference, the other optical element has a sub-aperture ratio comparable to that of the optical element. Surface processing on the other optical element or elements may be performed as described further above.

In order to – partially – compensate the temporal change in the optical property over the operational life, accurate information is needed about the temporal profile and the spatial extent (see below) of the optical property, for example about the temporal change in the surface figure, which corresponds to a temporally variable local deformation of the surface of the optical element. The methods with which this information can be obtained can be divided into two groups: measurement and simulation, with a combination of both methods also being possible.

In a variant, the temporal change in the optical property that is expected over the operational life of the optical element is determined on the basis of at least one measurement. The temporal change in the at least one optical property over the operational life of the optical element, which is also referred to below as long-term change, may be predicted by a prior measurement of the optionally temporally variable rate of temporal change and the spatial extent thereof (see below), for example in a saturation behavior. For example, this is possible if the temporal change or the rate is constant in time over the production time and operational life of the optical element. In this case, it is necessary for the measurement to enable an estimation of the long-term change in the optical property over the operational life of the optical element.

Such a measurement can be realized by virtue of a respective measurement being performed at multiple times in trial setup under controlled conditions and this time series allowing an unambiguous extrapolation into the future. It is important how the optical element is mounted between the individual measurements. The optical element should be mounted in a normal atmosphere that is kept constant. Moreover, it is typically necessary for the mounting to ensure that the effects of the long-term change in the optical property are not falsified. This relates in particular, but not exclusively, to the long-term change in the surface figure that is attributable to the action of a force.

Should the long-term change in the optical property not be constant over the production time and operational life, the approach described further above may likewise be used in principle, but it is optionally also possible to directly measure the state of the optical property during the operational life of the optical element. For example, this is possible if the long-term change in the surface figure is generated by the action of the gravitational force or by any other effect which is reset when the optical element is moved into its final operational position, in which the optical element remains over its operational life, and then acts on the optical element again after this time.

In relation to the action of the gravitational force, DE102017216458A1 has disclosed that it is possible to take account of a difference between the gravitational constant at the production location and at the use position of a mirror with a surface figure allowance when the mirror is produced. However, the long-term change in the surface figure of the mirror based on the action of the gravitational force is not taken into account in the surface figure allowance.

In a development of the above-described variant, the allowance is generated once a waiting time of at least 10 days, preferably of at least 40 days, in particular of at least 100 days, since a last processing of the optical element has elapsed, with a measurement of the temporally changeable optical property being performed once the waiting time has elapsed and the size of the allowance being determined on the basis of the measurement. As described further above, the measurement is only performed in this variant once a predetermined waiting time has elapsed after the last processing of the optical element during the manufacture. In this case, the waiting time is chosen so that a non-negligible proportion of the total time-dependent change in the optical property that is expected over the operational life of the optical element has occurred after the waiting time has elapsed.

In a further development of the variant described above, the allowance is generated once a waiting time of at least 10 days, preferably of at least 40 days, in particular of at least 100 days, since the last processing of the optical element has elapsed, with a respective measurement of the temporally changeable optical property being implemented at a time before and at a time after the waiting time has elapsed and the size of the allowance being determined on the basis of a difference between the two measurements and on the basis of a model-based expected temporal change in the optical property.

Given an operational life of the optical element of approx. 10 years and a temporal change in the optical property with a time-logarithmic profile, as caused by the action of the gravitational force for example, 50% of the temporal change in the optical property, for example in the form of the temporal change in the surface figure, may already be achieved after about 100 days in the above-described variants. This state can be measured directly still during production by targeted mounting of the optical element. In this case, it is possible to produce a surface figure allowance that is chosen such that the target surface shape in which the aberrations of the optical element are minimal is achieved at the time of measurement or shortly after the time of the measurement. By being brought into its final operational position, the target surface shape of the optical element arises again after the same waiting time within the operational life.

As a result of the absence of extrapolation, the method described here should be more accurate than the method described further above, with the accuracy particularly depending on the quality of the mounting. Independently of the selected measurement strategy, it is typically necessary for the aberrations or wavefront disturbances resulting from the long-term change in the optical property to be predicted with an accuracy greater

than 100 pm, preferably with an accuracy greater than 30 pm, in particular with an accuracy greater than 10 pm, in terms of the RMS value, e.g. in terms of the RMS5, i.e. the root mean square of the wavefront Zernike modes 5 to 36 and 49.

In a further variant, the temporal change in the optical property that is expected over the operational life of the optical element is determined on the basis of a model-based simulation, which preferably comprises finite element calculations. The long-term change or the rate of change over the operational life of the optical element may be predicted by suitable models and simulation techniques, e.g. by the finite element method. In this case, it is typically likewise necessary to predict the aberrations or wavefront disturbances resulting from the long-term change over the operational life with an accuracy greater than 100 pm, preferably with an accuracy greater than 30 pm, in particular with an accuracy greater than 10 pm, in terms of the RMS5. The accuracy of the simulation may be increased with dedicated calibration measurements, which are used to determine the model parameters in the finite element calculations.

In a further variant, the optical element forms one of the three optical elements in the lithography system, the substrates of which have the largest volume. The correction of long-term changes in the optical properties of optical elements which have a substrate with a large volume in comparison with other optical elements has proven advantageous.

In a further variant, the allowance compensates a proportion of at least 20%, preferably of at least 30%, in particular of at least 50%, of the aberrations that vary over the operational life of the optical element and are caused by the temporal change in the optical property over the operational life of the optical element. As described further above, the aberrations that vary over the operational life of the optical element can as a rule be approximately halved in the case that the allowance is chosen such that a proportion of approximately 50% of the expected temporal change in the optical property is compensated.

In a further variant, the temporal change in the optical property is caused by at least one of the following effects: thermal hysteresis, mechanical hysteresis, volume shrinkage, relaxing material compaction, for example after the irradiation described above with subsequent annealing, and radiation-induced compaction (optionally rarefaction) of the material in the substrate. The mechanical hysteresis of the material of the substrate, which is also referred to as delayed elasticity, may play a role, for example within a long-term change in the surface figure by the action of the gravitational force. It is understood that the list above is not exhaustive. Further effects that cause aberrations which vary over the operational life of the optical element include e.g. temporal changes in the surface layer stresses, etc.

In a variant, the optical property varies in spatially dependent fashion, the expected temporal change in the optical property is determined in spatially dependent fashion and the allowance corrects the change in the optical property in spatially dependent fashion. In addition to the temporal change, the optical property generally also varies in spatially dependent fashion. For example, this is the case if the optical property is the surface figure, i.e. the surface shape, of the optical surface of the substrate. In this case, a spatially dependent surface figure allowance that varies over the surface of the substrate is generated in order to partially compensate the deformation of the surface of the substrate that varies in spatially dependent fashion.

In a variant, the optical element forms an EUV mirror, and the substrate of the EUV mirror preferably consists in full or in part of a zero-expansion material. The zero-expansion material may be titanium-doped quartz glass or a glass ceramic, for example. These materials have a zero crossing of the coefficient of thermal expansion at a particular temperature, which is referred to as zero-crossing temperature.

A further aspect of the invention relates to an optical element, preferably a mirror, in particular an EUV mirror, wherein the optical element comprises aberrations that vary in time over an operational life of the optical element, with the aberrations reducing from the start of the operational life of the optical element as a starting point until a predetermined time, at which the aberrations are minimal, and increasing again after the predetermined time, with the predetermined time preferably being between 100 days and 8 years, more preferably being between 200 days and 6 years and in particular being between 2 years and 4 years. The start of the operational life is understood to mean that time at which the mirror is put into operation in a microlithography arrangement, for example in a lithography apparatus.

The above-described optical element may be produced by generating the above-described surface figure allowance on the surface of a substrate of the optical element. Should the optical element be a mirror, a reflective coating is applied to the surface of the substrate on which the surface figure allowance is generated (see above).

In an embodiment, the aberrations have a value of 100 pm or less, preferably of 30 pm or less, more preferably of 10 pm or less, at the predetermined time. The aberrations are measured as wavefront disturbances in the form of a respective RMS value at all points on the surface. The values specified above relate to that point on the surface where the aberrations are at a maximum. The values specified above relate to the RMS5 value, i.e. to the root mean square of the wavefront Zernike modes 5 to 36 and 49. It is understood that the above-described temporal behavior of the aberrations is retained if another suitable measure is used for determining aberrations, for example in the form of a quadratic mean over other Zernike polynomials or Zernike coefficients.

A further aspect of the invention relates to an apparatus for semiconductor lithography, in particular an EUV lithography apparatus, which comprises at least one such optical element. The apparatus for semiconductor technology can be an EUV lithography apparatus for exposing a wafer or some other apparatus for semiconductor technology, for example an inspection system, for example for inspecting masks, wafers or the like that are used in lithography.

Further features and advantages of the invention are evident from the following description of exemplary embodiments of the invention with reference to the figures of the drawing, which show details salient to the invention, and from the claims. The individual features can be realized in each case individually by themselves or as a plurality in any desired combination in a variant of the invention.

### BRIEF DESCRIPTION OF THE DRAWINGS

Exemplary embodiments are illustrated in the schematic drawing and are explained in the description that follows. In the drawing:

FIG. 1 shows a schematic meridional section through a projection exposure apparatus for EUV projection lithography,

FIG. 2A shows a schematic illustration of an EUV mirror from the projection exposure apparatus of FIG. 1 at a first time at which the EUV mirror is irradiated in order to generate a surface figure allowance,

FIG. 2B shows a schematic illustration of the EUV mirror at a second time at which a target surface shape of the surface of the mirror is attained as a result of a temporal change in the surface figure due to the action of the gravitational force,

FIG. 3 shows a schematic illustration of a long-term change in the surface figure of the mirror from FIGS. 2A and 2B on account of the action of the gravitational force, and

FIG. 4 shows a schematic illustration of aberrations of the EUV mirror that vary over time on account of the long-term change in the surface figure.

### DETAILED DESCRIPTION

In the description of the drawings that follows, identical reference signs are used for identical or functionally identical components.

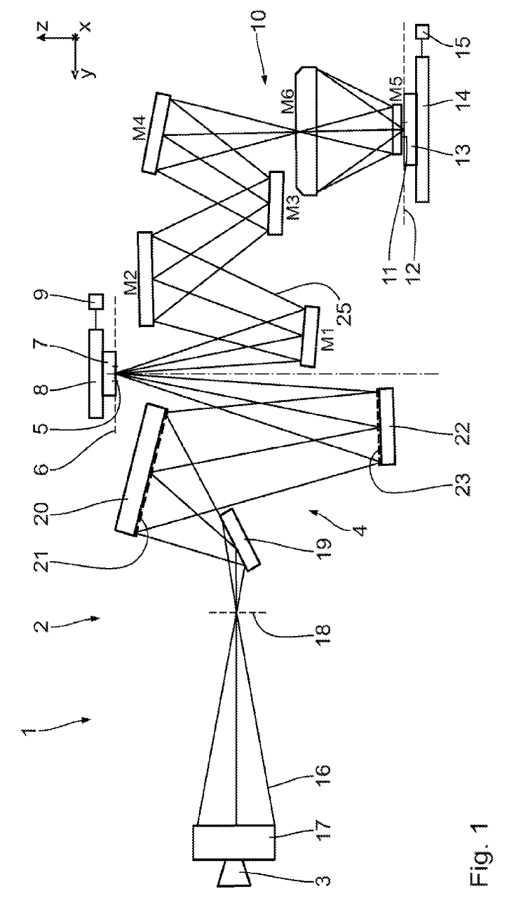

Salient constituent parts of an apparatus for semiconductor technology in the form of a microlithographic projection exposure apparatus 1, more precisely a projection exposure apparatus for EUV lithography, are described by way of example below with reference to FIG. 1. The description of the basic setup of the projection exposure apparatus 1 and the constituent parts thereof should not be understood to have a limiting effect.

An embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable in particular in a scanning direction with a reticle displacement drive 9.

For explanation purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable with a wafer displacement drive 15 in particular in the y-direction. The displacement, firstly, of the reticle 7 with the reticle displacement drive 9 and, secondly, of the wafer 13 with the wafer displacement drive 15 may be implemented so as to be synchronized with one another.

The radiation source 3 is an EUV radiation source. The radiation source 3 emits in particular extreme ultraviolet (EUV) radiation 16, which is also referred to below as used radiation, illumination radiation or illumination light. The used radiation has in particular a wavelength in the range of between 5 nm and 30 nm. The radiation source 3 can be a plasma source, for example an LPP (Laser Produced Plasma) source or a GDPP (Gas Discharge Produced Plasma) source. It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

Downstream of the collector mirror 17, the illumination radiation 16 propagates through an intermediate focus in an intermediate focal plane 18. The intermediate focal plane 18 may constitute a separation between a radiation source module, having the radiation source 3 and the collector mirror 17, and the illumination optics unit 4.

The illumination optics unit 4 comprises a deflection mirror 19 and, disposed downstream thereof in the beam path, a first facet mirror 20. The deflection mirror 19 may be a planar deflection mirror or alternatively a mirror with a beam-influencing effect that goes beyond the pure deflection effect. In addition to that or in an alternative, the deflection mirror 19 may be embodied as a spectral filter that separates a used light wavelength of the illumination radiation 16 from extraneous light of a wavelength differing therefrom. The first facet mirror 20 comprises a multiplicity of individual first facets 21, which are also referred to below as field facets. FIG. 1 illustrates only some of these facets 21 by way of example. In the beam path of the illumination optics unit 4, a second facet mirror 22 is arranged downstream of the first facet mirror 20. The second facet mirror 22 comprises a plurality of second facets 23.

The illumination optics unit 4 thus forms a doubly faceted system. This basic principle is also referred to as a fly’s eye integrator. The second facet mirror 22 is used to image the individual first facets 21 into the object field 5. The second facet mirror 22 is the last beam-shaping mirror or else actually the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise feasible. The penultimate mirror M5 and the last mirror M6 each have a through opening for the illumination radiation 16. The projection system 10 is a doubly obscured optical unit. The projection optics unit 10 has an image-side numerical aperture which is greater than 0.4 or 0.5 and which may also be greater than 0.6 and which may be for example 0.7 or 0.75.

Just like the mirrors of the illumination optics unit 4, the mirrors Mi may have a highly reflective coating for the illumination radiation 16.

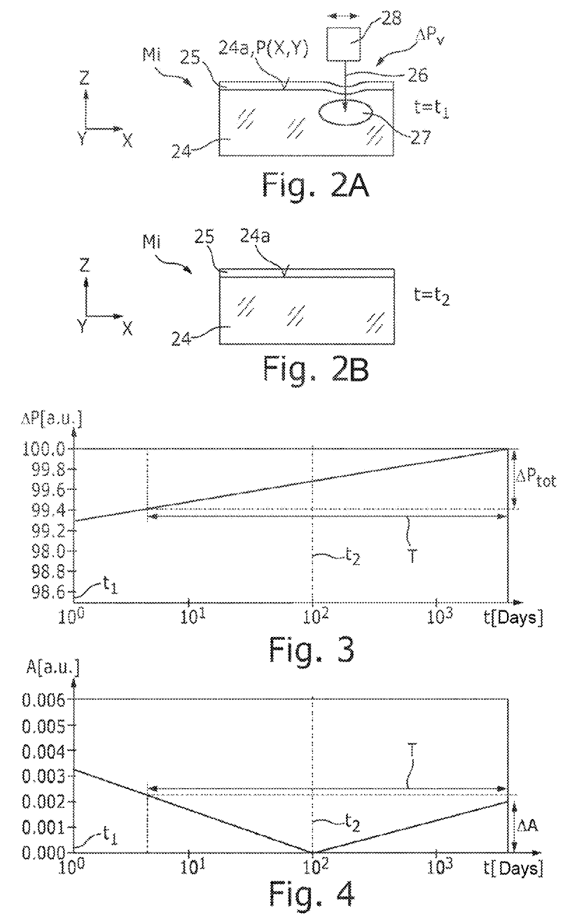

FIGS. 2A and 2B show a mirror Mi of the projection optics unit 10 from FIG. 1. The mirror Mi comprises a substrate 24 made of a zero-expansion material, which is titanium-doped quartz glass in the example shown. A reflective coating 25 formed from alternating layers of a high refractive index material and a low refractive index material is applied to a surface 24a of the substrate 24. In the example shown, in which the used wavelength is at 13.5 nm, the materials are silicon and molybdenum.

It is evident from FIG. 2A that the surface 24a of the substrate 24 has a target surface shape, which depends on the position x, y on the surface 24a and which is also referred to as surface figure P(x,y). To simplify matters, the assumption is made below that the target surface figure P(x,y), i.e. the target surface shape, is constant over the surface 24a, i.e. the target surface shape of the surface 24a of the substrate 24 is a flat surface 24a. The surface figure P(x,y) of the surface 24a of the mirror Mi may change over time over the operational life T (cf. FIG. 3) of the mirror Mi in the projection exposure apparatus 1 on account of various differing effects.

By way of example, FIG. 3 plots a temporal change ∆P (in arbitrary units) of the surface figure P, averaged over the surface 24a, as a function of the time t (in days), with this change being attributable to a deformation of the substrate 24 due to gravity. It is also evident from FIG. 3 that the temporal change ∆P in the surface figure P, which corresponds to the deformation of the surface 24a of the substrate 24, increases linearly over the operational life T of the mirror Mi on a logarithmic time scale.

The operational life T is indicated by a dotted line in FIG. 3 and denotes the time period over which the optical imaging quality of the mirror Mi should be optimal and hence aberrations should be minimal. In the example shown, the operational life T spans a time period between three days after the installation of the mirror Mi into the projection optics unit 10 (at the time t1, which may for example be a day or a significantly longer time period after the production of the mirror Mi) and ten years. In order to partially compensate for the varying aberrations A or wavefront errors which are illustrated in FIG. 4 and attributable to the temporal change ∆P in the surface figure P, it is possible to compensate a predetermined proportion of the total temporal change ∆Ptot of the surface figure P that is expected over the operational life T of the optical element Mi. In the example shown in FIG. 3, this predetermined proportion is 50% of the total temporal change ∆Ptot of the surface figure P that is expected over the operational life T. As evident from FIG. 3, the time t2 at which the proportion of the total temporal change ∆Ptot of the surface figure P over the operational life T of the mirror Mi reaches a value of 50% is 100 days.

The compensation which is generated in the form of a surface figure allowance ∆PV may be undertaken at or before the time t1 which corresponds to the time of installation of the mirror Mi into the projection exposure apparatus 1 and which is before the start of the operational life T of the mirror Mi. The surface figure allowance ∆PV illustrated in FIG. 2A for a predetermined position x,y on the surface 24a of the substrate 24 leads to the mirror Mi assuming its optimum surface shape or surface figure P(x,y) at the time t2, as evident from FIG. 2B.

As shown in FIG. 4, the aberrations A of the mirror Mi initially decrease on account of the surface figure allowance ∆PV because the surface figure allowance ∆PV shown in FIG. 2A reduces as a result of the action of the gravitational force until the second time t2 is reached, at which the aberrations A are minimal, and the surface 24a assumes the flat target surface shape shown in FIG. 2B. After the second time t2 and until the end of the operational life T of the mirror Mi, the aberrations A of the mirror Mi increase again since the surface 24a continues to deform on account of the action of the gravitational force as the substrate 24 continues to expand.

As a result of the compensation with the aid of the surface figure allowance ∆PV, the size of the change ∆A in the aberrations A over the operational life T of the mirror Mi may however, as a practical matter, be halved, when compared with a case in which no such compensation takes place, i.e. approx. 50% of the aberrations A that vary over the operational life T of the optical element Mi are compensated by the surface figure allowance ∆PV.

It is understood that a proportion other than 50% of the total expected temporal change ∆Ptot of the surface figure P over the operational life T of the mirror Mi can also be compensated as described further above, for example a proportion of 30% or of 40%.

The surface figure allowance ∆PV is generated by surface processing of the substrate 24, performed in the example shown by local irradiation with an electron beam 26 which causes compaction in the volume of the substrate 24, as indicated in FIG. 2A by a bordered region 27. The compaction leads to a change in the surface figure P(x,y) or the local surface figure allowance ∆PV. In order to generate a local surface figure allowance ∆PV at all positions x, y on the surface 24a, an electron gun 28 serving to generate the electron beam 26 is moved over the surface 24a, as indicated by a double-headed arrow. The irradiation with the electron beam 27 can be followed by an annealing step that brings about a decompaction of the substrate 24, as described in DE102018211596A1 cited at the outset. As described above, the size of the local surface figure allowance ∆PV at the time t1 was chosen such that the flat target surface shape of the surface 24a shown in FIG. 2B arises at a predetermined time t2.

Instead of the electron beam 26, an ion beam may also be used for the surface processing. Alternatively, the surface processing may be implemented by a material-removing method, for example by laser ablation. It is also possible to generate the surface figure allowance ∆PV for reducing the aberrations A at the mirror Mi by surface processing on another mirror Mj (j ≠ i) of the projection optics unit 10. Mirrors Mj that have a similar sub-aperture ratio to the mirror Mi, in particular, are suitable for this purpose.

For the reduction of the aberrations A described further above, it is necessary to determine the temporal change ∆P in the surface figure P that is expected over the operational life T of the optical element Mi with the greatest possible accuracy. The expected temporal change ∆P can in principle be determined by measurement, simulation or a combination of measurement and simulation. The expected temporal change ∆P can be measured at the mirror Mi itself or at a mirror Mi of the same type, which is arranged at the same use position in the projection optics unit 10.

Should the temporal change ∆P be constant over the production time and operational life T of the mirror Mi, the temporal change ∆P in the surface figure P over the operational life T of the mirror Mi can be estimated through a measurement or a plurality of measurements. For this purpose, a measurement can be performed at multiple times in trial setup under controlled conditions and this measurement allows an unambiguous extrapolation into the future.

The case where the temporal change ∆P in the surface figure P is generated by the above-described action of gravitational force or by any other effect which is reset when the mirror Mi is moved into its final use position in the projection optics unit 10 and then acts on the mirror Mi, which remains permanently in the use position, again after this time t1 gives rise to the option of measuring the state of the mirror Mi or the surface figure P at a time that still precedes the time t1. The time at which the temporal change ∆P in the surface figure P is measured may for example follow once a waiting time of at least 10 days, of at least 40 days or of at least 100 days has elapsed since the last time the optical element Mi was processed, and the measurement may still be performed during the manufacture. Since the temporal change ∆P in the surface figure P is reset upon installation into the projection optics unit 10, the measurement of the temporal change ∆P in the surface figure P in the event of a waiting time of e.g. 100 days after the last processing corresponds to the time t2, shown in FIG. 3 and FIG. 4, of 100 days after the time t1 of installation of the mirror Mi in the projection optics unit 10. Thus, the size of the surface figure allowance ∆PV, which is subsequently generated at the surface 24a of the mirror Mi, can therefore be determined on the basis of this measurement. In this case, the surface figure allowance ∆PV compensates the temporal change ∆P in the surface figure P up to the time t2, i.e. the flat target surface shape shown in FIG. 2B is likewise generated.

It is also possible that the allowance ∆PV is generated once a waiting time of at least 10 days, of at least 40 days or of at least 100 days since the last processing of the optical element Mi has elapsed, with a respective measurement of the temporal change ∆P in the surface figure P(x,y) being implemented at a time before and at a time after the waiting time has elapsed and the size of the surface figure allowance ∆PV being determined on the basis of a difference between the two measurements and on the basis of a model-based expected temporal change ∆P in the surface figure P(x,y).

In an alternative to a measurement or in addition, the temporal change ∆P in the surface figure P(x,y) that is expected over the operational life T of the optical element Mi may be determined on the basis of a model-based simulation, which e.g. is based on finite element calculations, the model parameters of which can be determined by calibration measurements.

The mirror Mi on which the above-described surface figure allowance ∆P is generated is one of the three mirrors Mi of the projection exposure apparatus 1, more precisely of the projection optics unit 10, the substrates 24 of which have the largest volume.

In the example described above, the temporal change ∆P in the surface figure P(x,y) was caused by an action of the gravitational force or a mechanical hysteresis or delayed elasticity of the material of the substrate 24. However, the temporal change ∆P in the surface figure P(x,y) may also be caused by one or more other effects, for example by a thermal hysteresis, a volume shrinkage, a relaxing material compaction or a radiation-induced compaction. The temporal change over the operational life T of the mirror Mi in optical properties other than the surface figure P(x,y) may also be at least partially compensated as described above.

What is claimed is:

1. A method for reducing aberrations of an optical element, comprising:
determining a temporal change in an optical property of the optical element that is expected over an operational life of the optical element, whereby the temporal change in the optical property over the operational life of the optical element causes varying aberrations, and
reducing the aberrations that vary over the operational life of the optical element by generating an allowance, which compensates at least a portion of a total temporal change in the optical property that is expected over the operational life.

2. The method as claimed in claim 1, wherein the optical element is in a lithography system, wherein the temporal change is a temporal change of the surface figure of a surface of a substrate of the optical element and wherein the allowance is a surface figure allowance.

3. The method as claimed in claim 1, wherein the allowance compensates a predetermined portion of the total temporal change in the optical property that is expected over the operational life of the optical element.

4. The method as claimed in claim 3, wherein the allowance compensates at least a 50% portion of the total temporal change in the optical property that is expected over the operational life of the optical element.

5. The method as claimed in claim 2, further comprising:
generating the surface figure allowance by processing the surface of the substrate, wherein said processing comprises material-removing processing of the surface of the substrate and/or irradiating the substrate.

6. The method as claimed in claim 2, wherein the surface figure allowance is generated by surface-processing of a further surface of a further substrate of a further optical element of the lithography system.

7. The method as claimed in claim 1, wherein the temporal change in the optical property that is expected over the operational life of the optical element is determined based on at least one measurement.

8. The method as claimed in claim 7, wherein the allowance is generated once a waiting time of at least 10 days since a last processing of the optical element has elapsed, and wherein the measurement of the temporal change in the optical property is performed once the waiting time has elapsed and a size of the allowance is determined based on the measurement.

9. The method as claimed in claim 8, wherein the allowance is generated once a waiting time of at least 100 days since the last processing of the optical element has elapsed.

10. The method as claimed in claim 7, wherein the allowance is generated once a waiting time of at least 10 days since a last processing of the optical element has elapsed, and wherein a respective measurement of the temporal change in the optical property is implemented at a time before and at a time after the waiting time has elapsed and a size of the allowance is determined based on a difference between the two measurements and on a model-based expected temporal change in the optical property.

11. The method as claimed in claim 10, wherein the allowance is generated once a waiting time of at least 100 days since the last processing of the optical element has elapsed.

12. The method as claimed in claim 1, wherein the temporal change in the optical property that is expected over the operational life of the optical element is determined based on a model-based simulation.

13. The method as claimed in claim 2, wherein the optical element forms one of three optical elements in the lithography system having larger-volume substrates relative to remaining substrates in the lithography system.

14. The method as claimed in claim 2, wherein the allowance compensates a portion of at least 20% of the aberrations that vary over the operational life of the optical element.

15. The method as claimed in claim 1, wherein the temporal change in the optical property is caused by at least one of the following effects: thermal hysteresis, mechanical hysteresis, volume shrinkage, relaxing material compaction and radiation-induced compaction.

16. The method as claimed in claim 1, wherein the optical property varies spatially dependently, wherein the expected temporal change in the optical property is determined spatially dependently, and wherein the allowance corrects the change in the optical property spatially dependently.

17. The method as claimed in claim 1, wherein the optical element forms an extreme ultraviolet (EUV) mirror, and wherein the substrate of the EUV mirror consists at least partly of a zero-crossing material.

18. An optical element exhibiting aberrations that vary in time over an operational life of the optical element, wherein the aberrations reduce from a start of the operational life until a predetermined time at which the aberrations are minimal, and increase after the predetermined time.

19. The optical element as claimed in claim 18, wherein the predetermined time is between 100 days and 8 years.

20. The optical element as claimed in claim 18, wherein the aberrations have a value of 100 pm or less at the predetermined time.

21. An apparatus for semiconductor lithography, comprising: at least one optical element as claimed in claim 18.
